(19) United States
(12) Patent Application Publication
(10) Pub. No.: US 2020/0294827 A1
(43) Pub. Date: Sep. 17, 2020

(54) NEEDLE DISPENSER FOR DISPENSING AND COLLECTING AN UNDERFILL ENCAPSULANT

(71) Applicant: Intel Corporation, Santa Clara, CA (US)

(72) Inventor: Florence PON, Folsom, CA (US)

(21) Appl. No.: 16/354,724

(22) Filed: Mar. 15, 2019

(51) Int. Cl. H01L 21/67; H01L 23/31; H01L 21/56

(52) U.S. Cl. CPC H01L 21/67126; H01L 21/563; H01L 23/3171

(57) ABSTRACT

Embodiments described herein provide a needle dispenser for use in dispensing and collecting an underfill encapsulant under a device on a substrate. In one scenario, the needle dispenser comprises: a reservoir; and a needle coupled to the reservoir. A tip of the needle is comprised of a first material and a body of the needle is comprised of a second material. The first material is more compliant than the second material. An outer surface of the needle is formed from a hydrophobic material and a core of the needle comprises a hydrophilic material. The needle also comprises channels extending along the needle. A solvent flows through at least one of the channels to soak the core. Additionally, openings formed in the needle's outer surface expose the core. The openings enable dispensing or absorbing of the underfill material.

### BACKGROUND

### Field

Embodiments described herein generally relate to substrates (e.g., semiconductor packages, printed circuit boards (PCB), etc.). More particularly, but not exclusively, embodiments described herein relate to a needle dispenser for dispensing and collecting underfill encapsulants.

### Background Information

An underfill encapsulant is a material that provides mechanical support and protection for interconnects (e.g., solder balls, micro bumps, columns, etc.) that couple a target component (e.g., a die, etc.) to a substrate (e.g., an organic substrate, an inorganic substrate, a printed circuit board (PCB), a redistribution layer (RDL), etc.). The underfill encapsulant also minimizes mechanical stress that is due to a coefficient of thermal expansion (CTE) mismatch between the different materials.

When using an underfill encapsulant to encapsulate interconnects coupling a target component to a substrate, a keep-out zone around the target component may be required. The keep-out zone provides an area away from un-targeted components where the underfill encapsulant can reside on the substrate. In this way, the un-targeted components and interconnects coupling the un-targeted components to the substrate do not come in contact with the underfill encapsulant. The keep-out zone also provides an area to insert a needle dispenser used to dispense the underfill encapsulant.

One drawback of a keep-out zone is that it is unused space that takes up valuable real-estate on a substrate. Typically, the keep-out zone is a border around the target component. For example, a size (e.g., a perimeter, an area, etc.) of the keep-out zone around the target can range from 0.5 millimeters (mm) to 1 mm. This large keep-out zone can limit the size or number of components that can placed or manufactured on a substrate.

One alternative to using the keep-out zone is flooding the entire surface of a substrate with an underfill encapsulant such that the underfill encapsulant encapsulates interconnects associated with all components on the substrate. For example, a first component may be coupled to a substrate via a first set of interconnects and a second component that is adjacent to the first component may be coupled to the substrate via a second set of interconnects. In order to secure and protect the first set of interconnects, an underfill encapsulant may be dispensed on a surface of the substrate. More specifically, the underfill encapsulant is used to encapsulate the entire surface of the substrate, which includes the first and second interconnects thereon. Consequently, the first and second sets of interconnects are encapsulated by the underfill encapsulant, even though the aim was to encapsulate the first set of interconnects. One drawback of flooding the entire surface of the substrate 293 is that it results in wasting the underfill encapsulant and in unnecessarily encapsulating interconnects that do not necessarily need to be encapsulated by the underfill encapsulant. Wasting the underfill encapsulant and unnecessarily encapsulating interconnects that do not need to be encapsulated by the underfill encapsulant undesirably increase costs associated with semiconductor packaging and manufacturing.

Furthermore, current techniques of dispensing underfill encapsulants require use of needle dispensers with stiff metallic needles. One drawback of these stiff metallic needles is that they cannot be brought in contact with the substrate, components on the substrate, or interconnects coupling the components to the substrate. Such contact is undesired because the stiff metallic needles may damage the above-referenced objects. Additionally, because such contact is undesired, the stiff metallic needles cannot be used to dispense underfill encapsulants unless a large enough keep-out zone is provided.

In view of the description provided above, currently available techniques of dispensing an underfill encapsulant remain suboptimal.

### BRIEF DESCRIPTION OF THE DRAWINGS

Embodiments described herein are illustrated by way of example and not a limitation in the figures of the accompanying drawings, in which like references indicate similar features. Furthermore, in the figures, some conventional details have been omitted so as not to obscure from the inventive concepts described herein.

FIGS. 1A-1B are cross sectional side view illustrations of a needle dispenser used for dispensing and collecting an underfill encapsulant, according to one embodiment.

FIGS. 2A-2B are cross sectional side view illustrations of a needle dispenser used for dispensing and collecting an underfill encapsulant, according to another embodiment.

FIGS. 3A-3B are cross sectional side view illustrations of a needle dispenser used for dispensing and collecting an underfill encapsulant, according to yet another embodiment.

FIGS. 4A-4B are cross sectional side view illustrations of a needle dispenser used for dispensing and collecting an underfill encapsulant, according to one more embodiment.

FIG. 5A is a plan view illustration of a needle that is part of a needle dispenser, according to one embodiment.

FIGS. 5B-5C are cross sectional side view illustrations of the needle in FIG. 5A.

FIGS. 6A-6E are cross sectional side view illustrations of a method of dispensing an underfill encapsulant on a substrate of a semiconductor package using a needle dispenser and of collecting the dispensed underfill encapsulant, according to one embodiment.

FIGS. 7A-7B are plan view illustrations of a device on an underfill encapsulant after some portions of the dispensed underfill have been collected by a needle dispenser, according to one embodiment.

FIG. 8 is a cross sectional illustration of a packaged system, according to one embodiment.

FIG. 9 is a schematic illustration of a computer, according to one embodiment.

### DETAILED DESCRIPTION

In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features, such as techniques of using an underfill encapsulant to encapsulate a component, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein are directed to a needle dispenser for dispensing and collecting an underfill encapsulant used to protect one or more interconnects (or other components) positioned on a substrate. The needle dispenser comprises a reservoir and a needle coupled to the reservoir. The needle directs an underfill encapsulant out of the reservoir. In an embodiment, the needle comprises: (i) a tip; (ii) a body coupled to the tip; (iii) a core; (iv) an outer surface; (v) one or more openings formed through the outer surface that expose the core; and (vi) one or more channels that run (e.g., extend, etc.) along the needle. In one embodiment, the needle's tip is formed from a first material while the needle's body is formed from a second material that differs from the first material. In one embodiment, the first material used to form the needle's tip is more compliant than the second material used to form the needle's body. In one embodiment, the entire needle (i.e., the body and the tip) are formed from the first material.

In one embodiment, the core of the needle is formed from a hydrophilic material and the outer surface of the needle is coated with or formed from a hydrophobic material. A solvent (e.g., acetone, isopropyl alcohol, any other suitable polar solvent, or any combination thereof) flows through at least one channel that runs (e.g., extends, etc.) along the needle to soak the needle's core to keep the hydrophilic core primed. At least one of openings that is formed through the needle's outer surface enables the core to collect (e.g., siphon, etc.) a material (e.g., an underfill encapsulant, etc.) on a substrate, a device on the substrate, or an interconnect coupling the device to the substrate.

Embodiments of the needle dispenser described herein have several advantages. One advantage is that the compliant material used to form the needle (or the tip of the needle) enables the needle to physically contact devices, interconnects coupling the devices to a substrate, and the substrate itself without damaging the devices, the interconnects, or the substrate. The ability of the needle to physically contact the devices, the interconnects, or the substrate assists with increasing yield by reducing or eliminating damage to the devices, the interconnects, and the substrate. Additionally, the use of a compliant material for the tip allows the tip to be displaced and extended below the target component. This allows for more precise and controllable dispensing of the underfill encapsulant.

Furthermore, the combination of the hydrophobic material used to form the core, the hydrophilic material used to form or coat the needle's outer surface, and the solvent that is infused into the core enables the needle to collect a material (e.g., an underfill encapsulant, etc.) on a substrate, a device on the substrate, or an interconnect coupling the device to the substrate. For example, embodiments of the needle described herein can clean up excess underfill encapsulant on a substrate by siphoning the excess underfill encapsulant back into the needle dispenser's core. Such embodiments can collect (e.g., siphon) an underfill encapsulant that is around or under a device, around or under an interconnect, or on a substrate. In this way, wasting of the underfill encapsulant can be minimized or eliminated.

Additionally, embodiments of the needle dispenser described herein can be used to dispense an underfill encapsulant to create a fillet under a device (e.g., a die, etc.) that is closer to the device than a fillet created using a stiff metallic needle. This is because the embodiments of the needle dispenser described herein enable the underfill encapsulant to be dispensed in any desired direction, unlike a stiff metallic needle that can only dispense an underfill encapsulant in a limited number of directions. This is also because the dispensed underfill encapsulant can be shaped by collecting a desired amount of the underfill encapsulant that is around or under a device coupled to a substrate by one or more interconnects. D₁spensing an underfill encapsulant in a desired direction and shaping the dispensed underfill encapsulant assists with reducing waste and creating a fillet with a desired shape, size, or profile. Also, the ability of the embodiments of the needle dispenser described herein to create a fillet with a desired shape, size, or profile assists with minimizing the keep-out zone below what current manufacturing tolerances allow. For example, a size (e.g., a perimeter, an area, etc.) of the keep-out zone can be reduced from 1 millimeter (mm) to 0.5 mm or less (e.g., any value ranging from 0.125 mm to 0.5 mm, etc.). Furthermore, the ability of the embodiments of the needle dispenser described herein to dispense an underfill encapsulant in a desired direction and to shape the dispensed underfill encapsulant obviates the need to flood the entire surface of a substrate with the underfill encapsulant, as described above. Doing away with flooding the surface of the substrate assists with avoiding waste associated with performing underfill encapsulation operations.

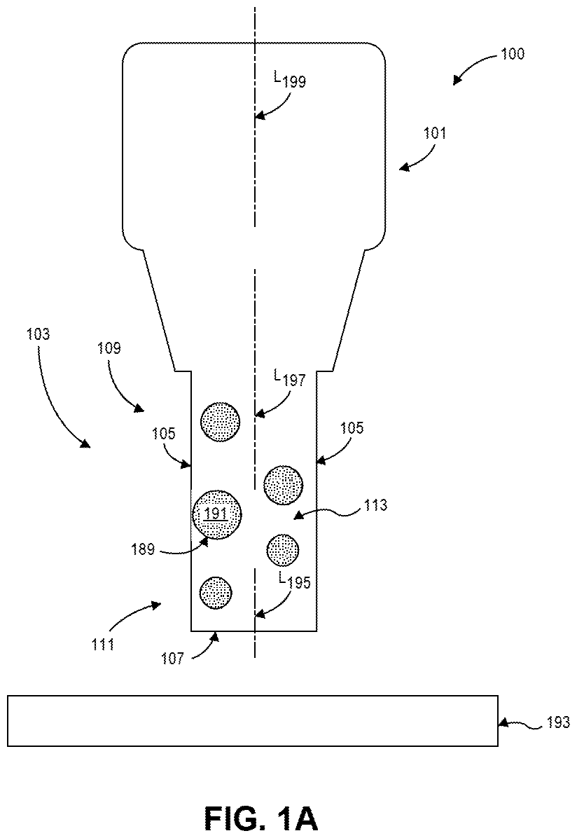

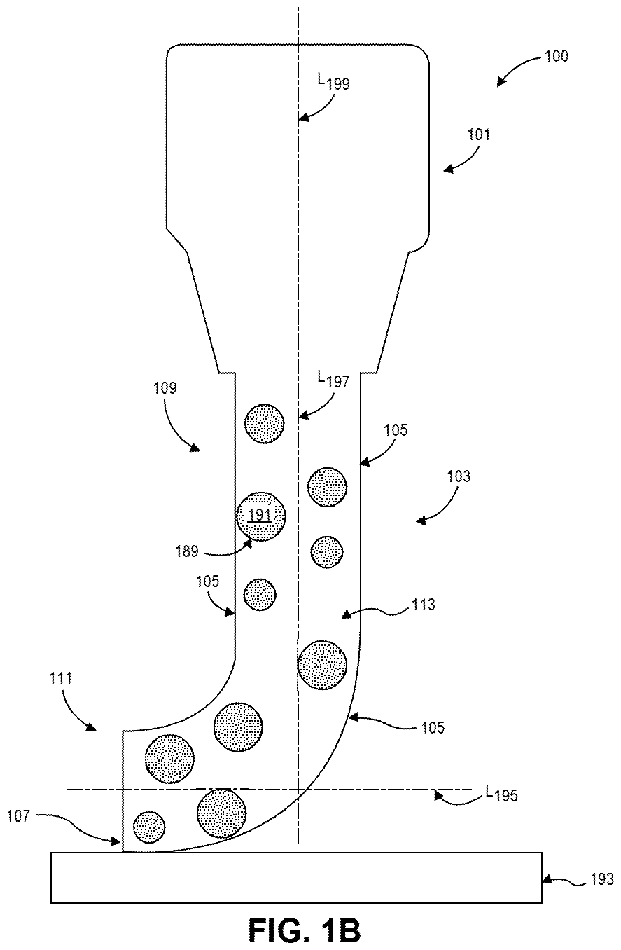

FIGS. 1A-1B are cross sectional side view illustrations of a needle dispenser 100 used for dispensing and collecting an underfill encapsulant, according to one embodiment. With regard now to FIG. 1A, a needle dispenser 100 that is above a substrate 193 is shown. The substrate 193 can be any known substrate (e.g., an organic substrate, an inorganic substrate, a semiconductor package, a redistribution layer (RDL), a board (e.g., a printed circuit board, a motherboard, etc.), an interposer substrate, etc.).

The needle dispenser 100 comprises a reservoir 101 and a needle 103 coupled to the reservoir 101. The reservoir 101 can house a material (e.g., an underfill encapsulant, etc.) to be dispensed through the needle 103. The reservoir can be formed from metal, plastic, or any other suitable material(s) used to form reservoirs known in the art.

As shown, the needle 103 comprises a body 109 and a tip 111. The body 109 has sidewalls 105 that couple the tip 111 to the reservoir 101. In one embodiment, the tip 111 includes an exit opening 107. The material (e.g., an underfill encapsulant, etc.) housed in the reservoir 101 can flow out of the needle 103 through the exit opening 107. In one embodiment, the needle 103 is a micro machined needle.

In one embodiment, the needle 103 is constructed to have an outer surface 113 formed from a hydrophobic material (or coated with a hydrophobic material) and a core 191 (partially shown) that is formed from a hydrophilic material. The core 191 is exposed via openings 189, which allow for a material (e.g., an underfill encapsulant, etc.) to be collected (e.g., siphoned, etc.) by the core 191. In one embodiment, one or more channels (not shown in FIG. 1A) run (e.g., extend, etc.) along the needle 103. In this embodiment, a solvent (not shown) flows through at least one channel that runs (e.g., extends, etc.) along the needle to soak the core 191. Soaking the core 191 with the solvent (not shown) primes the core and enables the core 191 to collect a material (e.g., an underfill encapsulant, etc.) on the substrate 193. Examples of a solvent include, but are not limited to, acetone, isopropyl alcohol, any other polar solvent, and any combination thereof.

As illustrated in FIG. 1A, the needle 103 extends downwards from the reservoir 101. In one embodiment, the needle 103 is aligned with the reservoir 101. A center line L₁₉₉ is aligned with center lines L₁₉₇ and L₁₉₅. More specifically, a center line L₁₉₉ of the reservoir 101 is parallel and coincident to a center line L₁₉₇ of the body 109 and a center line L₁₉₅ of the tip 111.

In one embodiment, a material used to form the tip 111 differs from a material used to form the body 109. In one embodiment, the material used to form the tip 111 is more compliant than the material used to form the body 109. Examples of the material used to form the tip 111 are a rubber, a compliant polymer, or a combination thereof. Examples of the material used to form the body 109 are stiff metals, stiff metal alloys, stiff plastics, or a combination thereof. In one embodiment, the entire needle 103 is formed from a compliant material (e.g., a rubber, a compliant polymer, a combination thereof, etc.). That is, there may be no discernible boundary between the body 109 and the tip 111.

Moving on to FIG. 1B, the needle dispenser 100 is brought in contact with the substrate 193. As shown, the tip 111 of the needle 103 is displaced (e.g., by deforming, bending, etc.) when brought in contact with substrate 193 such that the center line L₁₉₅ of the tip 111 is no longer parallel with center lines L₁₉₉ and L₁₉₇. In one embodiment, the displacement of the tip 111 causes the center line L₁₉₅ to intersect the center line L₁₉₇. In one embodiment, the center line L₁₉₅in FIG. 1B is substantially perpendicular to the center lines L₁₉₉ and L₁₉₇. The displacement of the tip 111 enables a material (e.g., an underfill encapsulant, etc.) to be dispensed onto the substrate 193 in a direction that substantially aligns with the center line L₁₉₅. One advantage of the displacement property of the tip 111 is that it enables a material (e.g., an underfill encapsulant, etc.) to be dispensed on or collected from the substrate 193 in a more precise manner than was previously available (e.g., when compared to an unbending needle whose tip is formed from a stiff material like metal, etc.). Furthermore, because the tip 111 is formed from a compliant material (e.g., rubber, compliant polymer, a combination thereof, etc.), the tip 111 does not damage the substrate 193 when the tip 111 is in contact with the substrate 193.

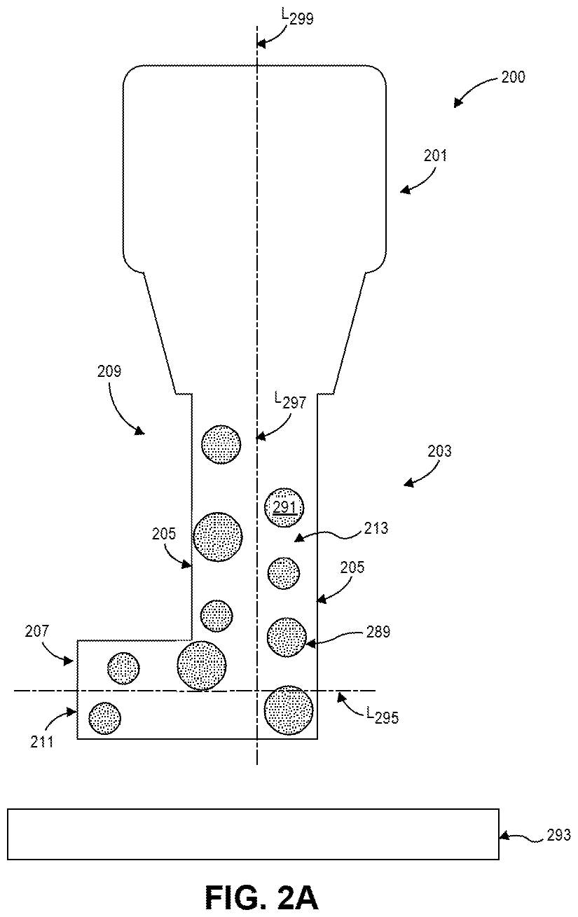

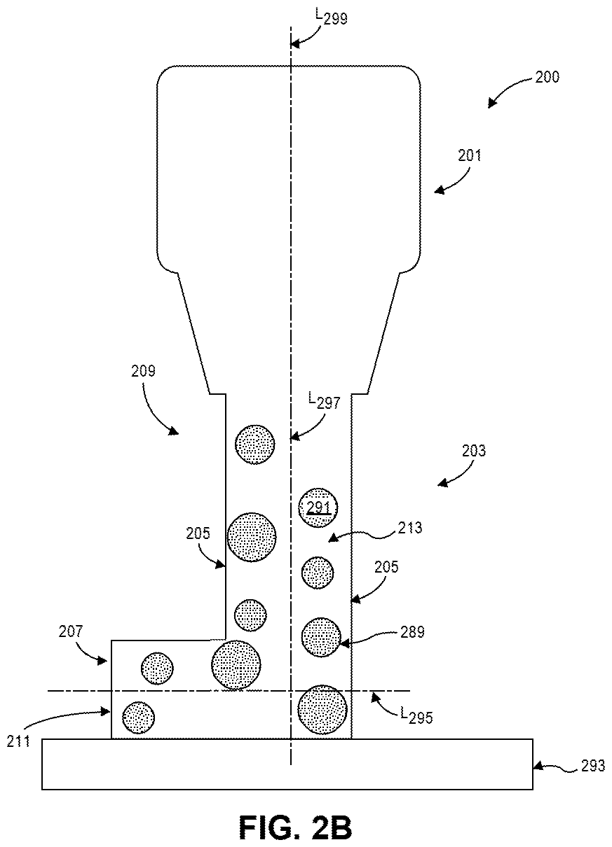

FIGS. 2A-2B are cross sectional side view illustrations of an additional embodiment of a needle dispenser 200 that can dispense or collect a material (e.g., an underfill encapsulant, etc.) onto or from a substrate 293, respectively. The needle dispenser 200 includes parts or components that are similar to those described above in connection with FIGS. 1A-1B. For brevity, these similar parts or components are not described again in connection with FIG. 2A or 2B unless the description is necessary.

Referring now to FIG. 2A, a needle dispenser 200 above a substrate 293 is shown. The needle dispenser 200 is similar to the needle dispenser 100 described above in connection with FIGS. 1A-1B, with the exception that the tip 211 of the needle dispenser 200 differs from the tip 111 of the needle dispenser 100. More specifically, the tip 211 is not parallel to the body 209 and the reservoir 201. That is, a center line L₂₉₅ of the tip 211 is not parallel to a center line L₂₉₇ of the body 209 and a center line L₂₉₉ of the reservoir 201. For example, in FIG. 2B, the center line L₂₉₅ of the tip 211 is substantially orthogonal to the center line L₂₉₇ of the body 209 and the center line L₂₉₉ of the reservoir 201. In some scenarios, because the tip 211 has an angled center line L₂₉₅ relative to the center lines of the body 209 and the reservoir 201, there is no need to bring the tip 211 into contact with the substrate 293 in order to dispense a material (e.g., an underfill encapsulant, etc.) in a desired direction. It is, however, to be appreciated that the tip 211 may be brought in contact with the substrate 293.

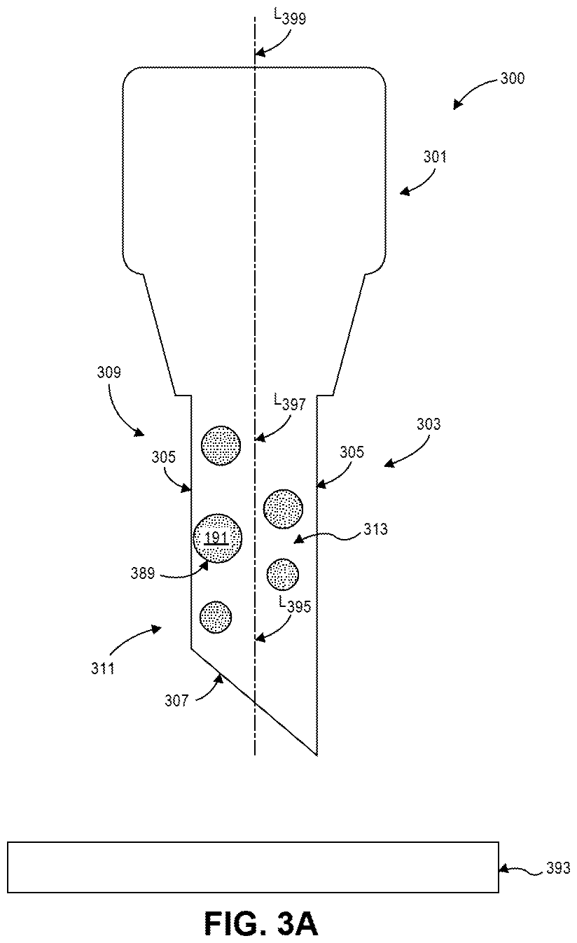

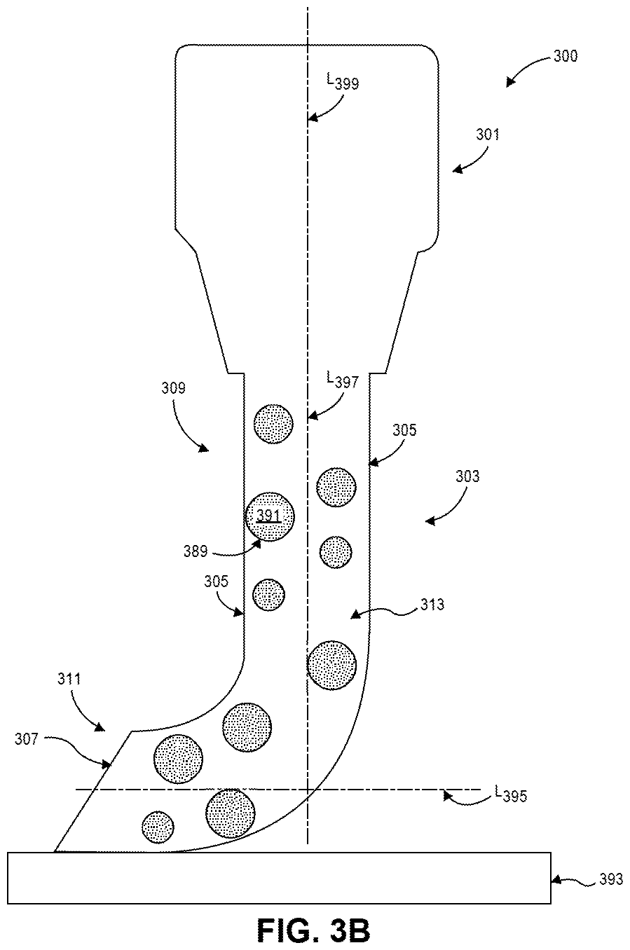

FIGS. 3A-3B are cross sectional side view illustrations of another embodiment of a needle dispenser 300 that can dispense or collect a material (e.g., an underfill encapsulant, etc.) onto or from a substrate 393, respectively. The needle dispenser 300 includes parts or components that are similar to those described above in connection with FIGS. 1A-1B. For brevity, these similar parts or components are not described again in connection with FIG. 3A or 3B unless the description is necessary.

With regard now to FIG. 3A, a needle dispenser 300 above a substrate 393 is shown. The needle dispenser 300 is similar to the needle dispenser 100 described above in connection with FIGS. 1A-1B, with the exception that the tip 311 of the needle dispenser 300 differs from the tip 111 of the needle dispenser 100. More specifically, the tip 311 is tapered.

Moving on to FIG. 3B, the needle dispenser 300 is brought in contact with the substrate 393. As shown, the tip 311 of the needle 303 is displaced (e.g., deformed, bent, etc.) when brought in contact with substrate 393. Stated differently, when the needle dispenser 300 is brought in contact with substrate 393, the center line L₃₉₅ of the tip 311, which was previously parallel to the center lines L₃₉₉ and L₃₉₇, is no longer substantially parallel to the center lines L₃₉₉ and L₃₉₇. The advantages that accrue from the needle dispenser 300 are similar to or the same as the advantages described above in connection with FIGS. 1A-1B.

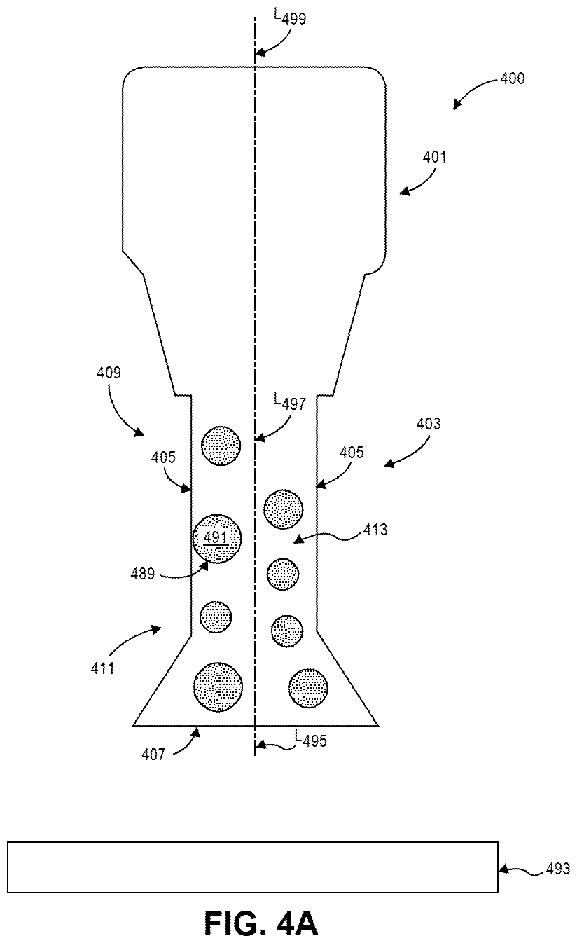

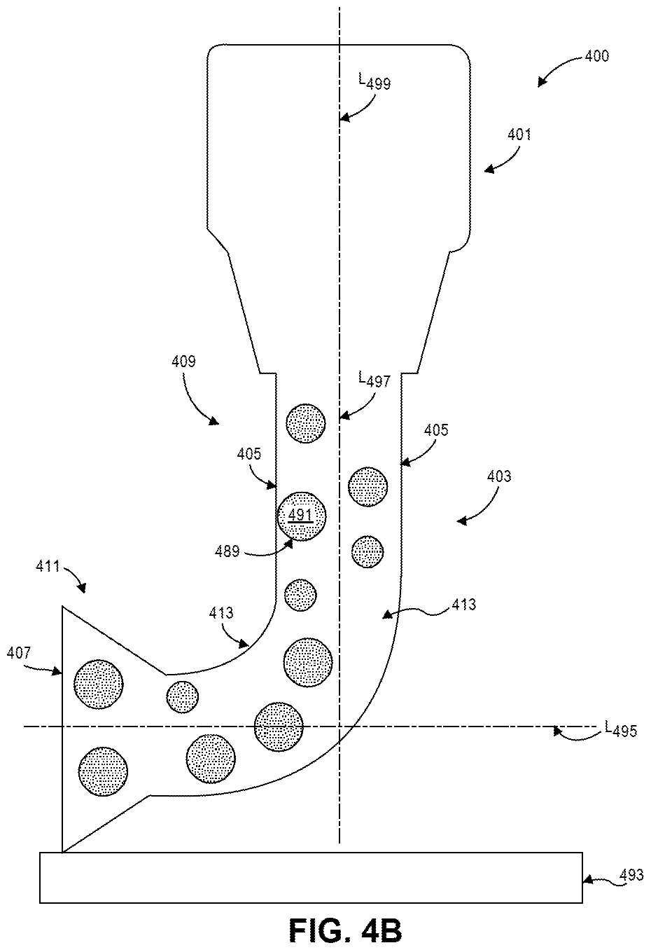

FIGS. 4A-4B are cross sectional side view illustrations of a needle dispenser 400 that can dispense or collect a material (e.g., an underfill encapsulant, etc.) onto or from a substrate 493, respectively. The needle dispenser 400 includes parts or components that are similar to those described above in connection with FIGS. 1A-1B. For brevity, these similar parts or components are not described again in connection with FIG. 4A or 4B unless the description is necessary.

With regard now to FIG. 4A, a needle dispenser 400 above a substrate 493 is shown. The needle dispenser 400 is similar to the needle dispenser 100 described above in connection with FIGS. 1A-1B, with the exception that the tip 411 of the needle dispenser 400 differs from the tip 111 of the needle dispenser 100. More specifically, the tip 411 is flared.

Moving on to FIG. 4B, the needle dispenser 400 is brought in contact with the substrate 493. As shown, the tip 411 of the needle 403 is displaced (e.g., deformed, bent, etc.) when brought in contact with substrate 493. Stated differently, when the needle dispenser 401 is brought in contact with substrate 493, the center line L₄₉₅ of the tip 411, which was previously parallel to the center lines L₄₉₉ and L₄₉₇, is no longer substantially parallel to the center lines L₄₉₉ and L₄₉₇. The advantages that accrue from the needle dispenser 400 are similar to or the same as the advantages described above in connection with FIGS. 1A-1B.

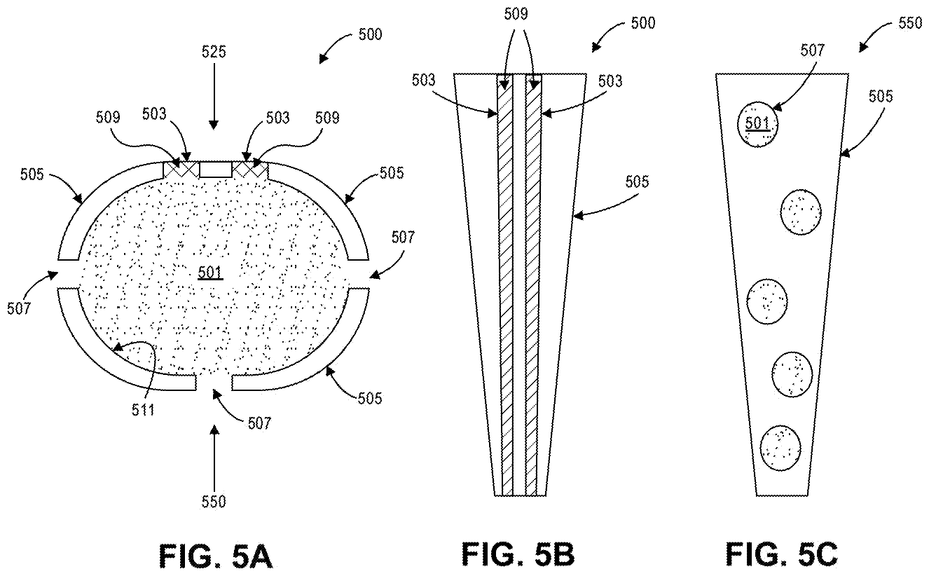

FIG. 5A is a cross sectional plan view illustration of a needle 500, according to one embodiment. The needle 500 can be similar to or the same as any of the needles (e.g., needles 103, 203, 303, 403, etc.) described above in connection with FIGS. 1A-4B. The needle 500 may be viewed from two points of view (POVs) 525 and 550. The needle 500, as viewed from the POVs 525 and 550, is described in more detail below in connection with FIGS. 5B and 5C.

With regard now to FIG. 5A, a cross sectional plan view illustration of the needle 500 is shown. As shown, the needle 500 comprises: (i) a core 501 formed from a hydrophilic material; (ii) an inner surface 511; (iii) an outer surface 505 formed from or coated with a hydrophobic material; (iv) multiple channels 503 between the inner surface 511 and the outer surface 505; (v) multiple openings 507 formed through the inner surface 511 and the outer surface 505 to expose the core 511; and (vi) a solvent 509 passing through the channels 503 that soaks the core 501. It is be appreciated that only one channel 503 may be formed in the needle 500. It is also to be appreciated that only one opening 507 may be formed in the needle 500.

The core 501 can be used to collect a material (e.g., an underfill encapsulant, etc.) by siphoning the material. The needle 500's outer surface 505 is hydrophobic to keep the needle 500 clean, and the inner core 501 is made of a hydrophilic absorbent material soaked in a solvent 509 passing through the channels 503 to help reduce the viscosity of the material (e.g., an underfill encapsulant, etc.) and increase the core 501's ability to collect material.

Moving on FIG. 5B, the needle 500 illustrated in FIG. 5A is shown from a POV 525. More specifically, FIG. 5B is a side view illustration of the needle 500 shown in FIG. 5A. As shown, the channels 503 run (e.g., extend, etc.) along the length of the needle 500. In this way, the solvent 509 can be used to soak the entire length of the core 501. In one embodiment, the channels 503 are formed between the outer surface 505 (shown in FIG. 5A) and the inner surface 511 (shown in FIG. 5A). In one embodiment, the channels 503 are formed on the inner surface 511 (shown in FIG. 5A) and do not pass through the outer surface 505 (shown in FIG. 5A).

Referring now to FIG. 5C, the needle 500 illustrated in FIG. 5A is shown from a POV 550. More specifically, FIG. 5C is another side view illustration of the needle 500 shown in FIG. 5A. As shown, the openings 507 are formed through the outer surface 505 (shown in FIG. 5A) and the inner surface 511 (shown in FIG. 5A) to expose the core 501. In this way, the core 501 can be used to collect a material (e.g., an underfill encapsulant, etc.).

It is to be appreciated that the locations, sizes, and/or shapes of the channels 503 and the openings 507 shown in FIGS. 5A-5C are exemplary in nature. For example, channels 503 may be located at any location around the needle 500 (i.e., the channels are not limited to be formed along one side of the needle 500). In some embodiments, channels 503 may be equally or unequally spaced around a perimeter of the needle 500. Additionally, in some embodiments, the openings 509 may have uniform or non-uniform sizes. For example, the openings 509 proximate to the tip of the needle 500 may be smaller or larger than openings 509 proximate to the beginning of the needle 500.

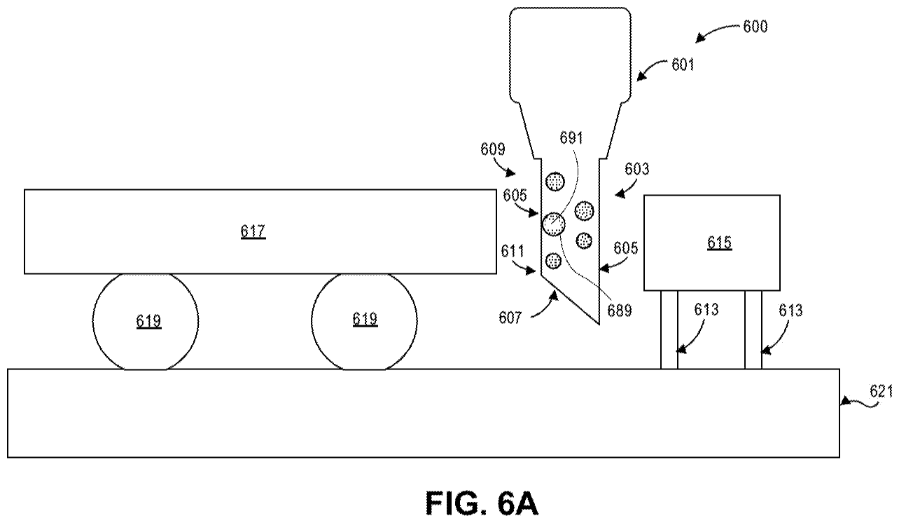

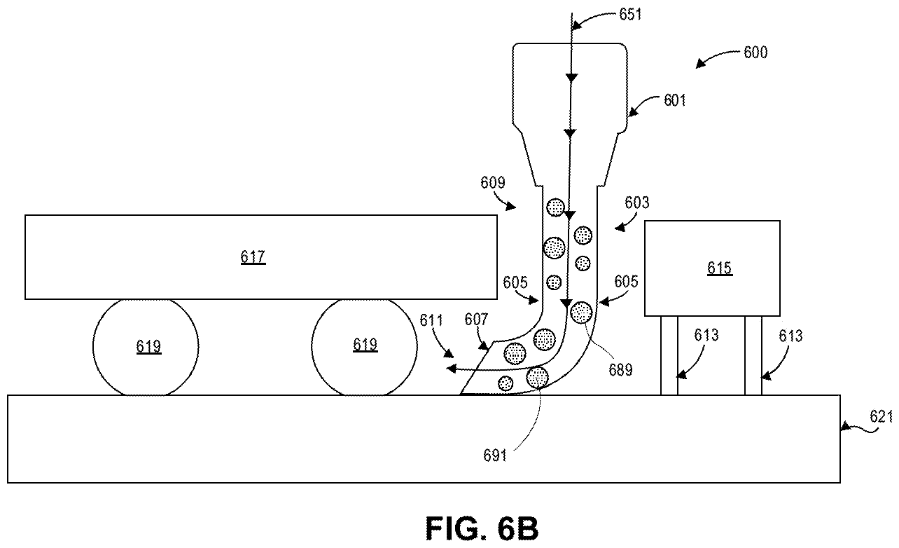

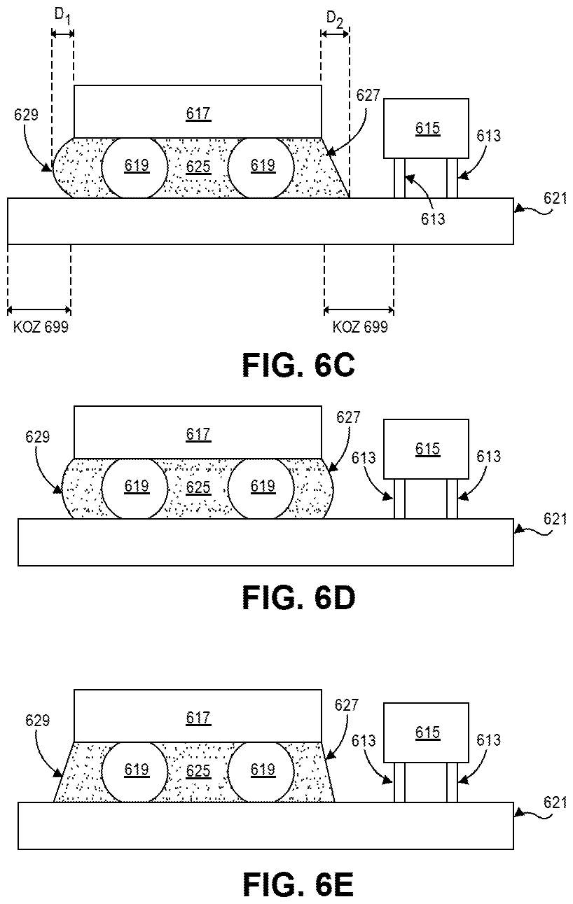

Moving on to FIGS. 6A-6E, a method of dispensing an underfill encapsulant 625 under a device (e.g., a die, etc.) 617 is shown. With regard now to FIG. 6A, a first device 617 that is coupled to a substrate 621 using interconnects (e.g., solder bumps, micro bumps, pillars, etc.) 619 is shown. Additionally, a second device 615 (e.g., a die, etc.) is adjacently located on the substrate 621 near the first device 617. The second device 615 is coupled to the substrate 621 using interconnects 613, which may be solder bumps, micro bumps, or pillars. Next, and as shown in FIG. 6A, a needle dispenser 600 is placed in the gap between the first device 617 and the second device 615. In one embodiment, the needle dispenser 600 is similar to or the same as any of the needle dispensers described above in connection with FIGS. 1A-5C. The needle dispenser 600 comprises a reservoir 601 and a needle 603 coupled to the reservoir 601. In one embodiment, the needle 603 is a micro machined needle. The needle 603 comprises a body 609 and a tip 611. The body 609 has sidewalls 605 that couple the tip 611 to the reservoir 601. In one embodiment, the tip 611 includes an exit opening 607. The needle 603 also includes openings 689 that expose a core 691 of the needle 603. Furthermore, the needle 603 includes one or more channels (not shown) that run (e.g., extend, etc.) along the length of the needle 603. An underfill encapsulant 625, which is described below in connection with FIGS. 6C-6E, is housed in the reservoir 601. In one embodiment, the underfill encapsulant 625 can flow out of the needle 603 through the exit opening 607.

Moving on FIG. 6B, the needle 603 of the needle dispenser 600 is brought in contact with a surface of the substrate 621. More specifically, the needle 603 is placed under the device 617 in a location that is adjacent to one of the interconnects 619. That is, the tip 611 of the needle 603 is under the device 617 and within an outer perimeter of the device 617.

In one embodiment, the needle 603 (or the tip 607) is formed from a compliant material. This compliant material enables the needle 603 to be displaced (e.g., deformed, bent, etc.) and maneuvered underneath the device 617 when the needle 603 is in contact with the substrate 621. That is, the tip 607 of the needle 603 is within an outer perimeter of the device 617. One advantage of forming the needle 603 (or the tip 607) from a compliant material is that the needle 603 (or the tip 607) can physically contact the devices 617 and 615, interconnects 619 and 613 coupling the devices 617 and 615 to the substrate 621, and the substrate 621 itself without damaging the devices 617 and 615, the interconnects 619 and 613, or the substrate 621. The ability of the needle 603 to physically contact the devices 617 and 615, interconnects 619 and 613 coupling the devices 617 and 615 to the substrate 621, and the substrate 621 assists with increasing yield associated with performing an underfill encapsulation operation by reducing or eliminating damage to the devices 617 and 615, interconnects 619 and 613 coupling the devices 617 and 615 to the substrate 621, and the substrate 621. When the needle 603 is in contact with the substrate 621 and under the device 617, the underfill encapsulant 625 is dispensed in a direction 651.

Moving on to FIG. 6C, the underfill encapsulant 625 under the device 617 and encapsulating the interconnects 619 is shown. In one embodiment, an outer perimeter of the device 617 is smaller than an outer perimeter of the underfill encapsulant 625 that is encapsulating the interconnects 619. In one embodiment, a keep-out zone 699 is around the underfill encapsulant 625 encapsulating the interconnects 619. For example, the keep-out zone 699 extends from a sidewall of the device 617 to a sidewall of the device 615, as shown in FIG. 6C. Furthermore, since dispensing of the underfill encapsulant 625 is controlled, an edge of the underfill encapsulant 625 may extend out from under the device 617 a distance D₁ or D₂ that is less than the width of the keep-out zone 699. For example, the width of the keep-out zone 699 may be 0.5 mm or less (e.g., any value ranging from 0.125 mm to 0.5 mm, etc.), and the distances D₁ and D₂ may be less than Z. For example, one or both of the distances D₁ and D₂ may range from 25% of the keep-out zone 699 to 50% of the keep-out zone 699. It is to be appreciated that the keep-out zone 699 may be larger than the distances D₁ and D₂ in order to accommodate the needle 603. However, due to the use of a needle 603 with a compliant tip (or a compliant tip and body), the keep-out zone 699 in embodiments disclosed herein is still smaller than existing manufacturing tolerances allow.

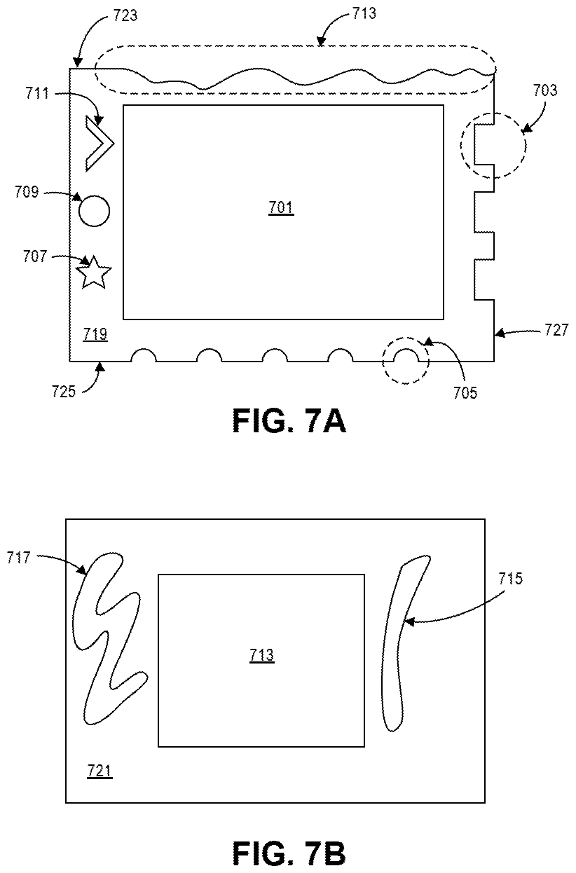

With regard again to FIG. 6A, the needle dispenser 600 can be used to control the size, shape, or profile of the fillets 627 and 629. In a further embodiment, and as explained below in connection with FIGS. 7A-7B, the needle dispenser 600 can be used to collect portions of the underfill encapsulant 625 so that the fillets 627 and 629 have a desired size, shape, or profile. In one embodiment, using the needle dispenser 600 to dispense the underfill encapsulant 625 enables different types of fillets to be formed under the device 617. For example, and as shown in FIGS. 6C and 6E, a first fillet 627 has a sloped profile. For another example, and as shown in FIGS. 6C and 6D, a second fillet 629 has a concave profile. It is to be appreciated that the fillet 627 can also have a concave profile, as shown in FIG. 6D. It is also to be appreciated that the fillet 629 can have a sloped profile, as shown in FIG. 6E. Additionally, it is to be appreciated that the fillets 627, 629 can have any profile known in the art (e.g., a convex profile, etc.).

FIGS. 7A-7B are plan view illustrations of a device on an underfill encapsulant after at least some portions of the dispensed underfill have been collected by a needle dispenser, according to one embodiment. Referring now to FIG. 7A, a device 701 that is on an underfill encapsulant 719 is illustrated. As shown, portions of the underfill encapsulant 719 have been collected by a needle dispenser, for example, the needle dispenser described above in connection with FIGS. 5A-5C. In one embodiment, the needle dispenser (not shown in FIGS. 7A-7B) can be used to create desired voids 711, 709, 707 having any shape or size in the underfill encapsulant 719 by collecting portions of the underfill encapsulant 719. For example, the void 711 is shown as a chevron, the void 709 is a circle, and the void 707 is a star. In yet another embodiment, portions of edges of the underfill encapsulant 719 can be removed to prevent the underfill encapsulant 719 from bleeding onto a substrate, interconnects not associated with the device 701, or other devices on the substrate. In one embodiment, the outer perimeter of the underfill encapsulant 719 has edges that have non-linear shapes after portions of the edges have been collected by an embodiment of a needle dispenser described herein. For example, an edge 723 can have a wavy shape 713, an edge 727 can have notches 703 formed therein, and an edge 725 can have notches 705 formed therein. It is to be appreciated that the edges of the underfill encapsulant 719 can have any known shape, size, or profile.

Moving on to FIG. 7B, a device 713 that is on an underfill encapsulant 721 is illustrated. As shown, portions of the underfill encapsulant 721 have been collected by a needle dispenser, for example, the needle dispenser described above in connection with FIGS. 5A-5C. In one embodiment, the needle dispenser (not shown in FIGS. 7A-7B) can be used to create voids 717, 715 with desired shapes or sizes in the underfill encapsulant 719 by collecting portions of the underfill encapsulant 719.

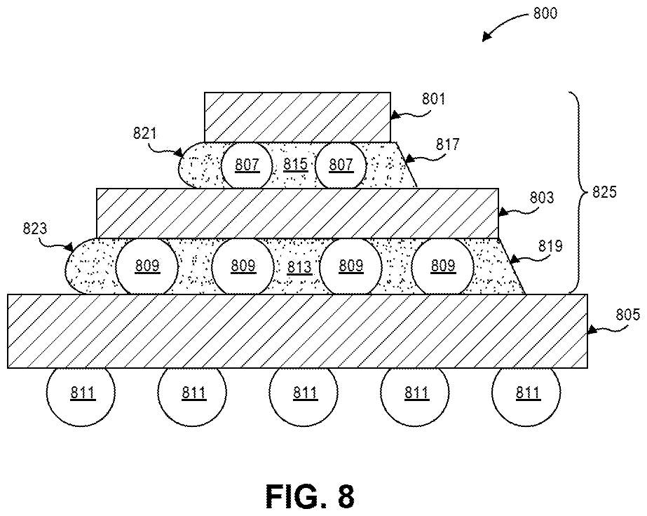

FIG. 8 illustrates a cross sectional side view illustration of packaged system 800 that comprises a semiconductor package 825, where the semiconductor package 825 comprises an device 801 coupled to a substrate 803 that is coupled to a board (e.g., a printed circuit board, motherboard, etc.), according to one embodiment. The semiconductor package 825 comprises device 801 coupled to a substrate 803 via interconnects 807 that are encapsulated in an underfill encapsulant 815. As shown, the underfill encapsulant 815 has two fillets 817 and 821, where the fillet 821 has a concave profile and the fillet 817 has a sloped profile. It is to be appreciated that each of the fillets 821, 817 may have any known profile (e.g., a convex profile, a sloped profile, a concave profile, etc.). The semiconductor package further comprises a substrate 803 coupled to a board 805 via interconnects 809 that are encapsulated in an underfill encapsulant 813. As shown, the underfill encapsulant 813 has two fillets 823 and 819, where the fillet 823 has a concave profile and the fillet 819 has a sloped profile. It is to be appreciated that each of the fillets 823, 819 may have any known profile (e.g., a convex profile, a sloped profile, a concave profile, etc.). The semiconductor package 825 further comprises interconnects 811 formed on a surface of the board 805. In one embodiment, the semiconductor package 825 is similar to or the same as any one of the semiconductor packages described above in connection with one or more of FIGS. 1A-7B.

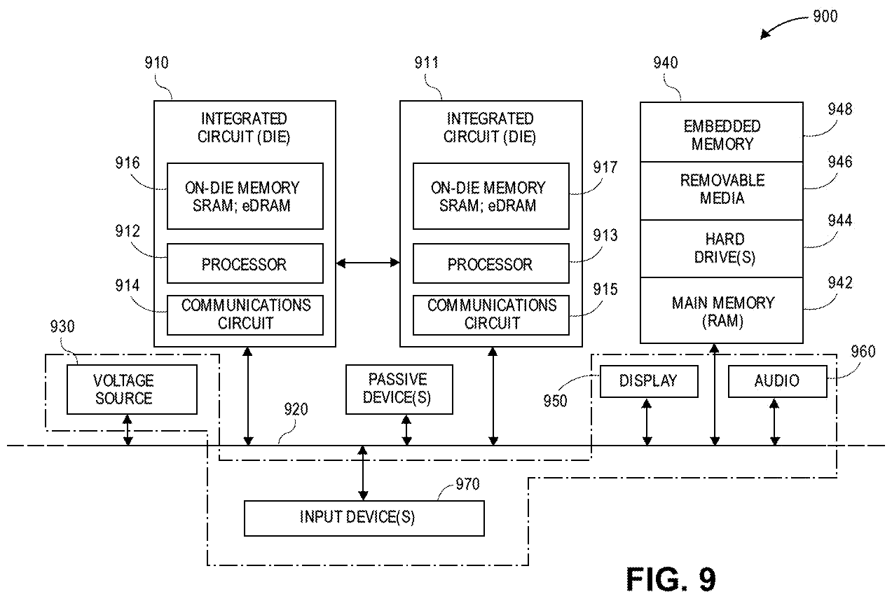

FIG. 9 illustrates a schematic of computer system 900 according to an embodiment. The computer system 900 (also referred to as an electronic system 900) can include a semiconductor package comprising an underfill encapsulant that has been dispensed or collected in accordance with any of the embodiments and their equivalents as set forth in this disclosure. The computer system 900 may be a mobile device, a netbook computer, a wireless smart phone, a desktop computer, a hand-held reader, a server system, a supercomputer, or a high-performance computing system.

The system 900 can be a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 910. In one embodiment, the voltage source 930 supplies current to the integrated circuit 910 through the system bus 920.

The integrated circuit 910 is electrically coupled to the system bus 920 and includes any circuit, or combination of circuits according to an embodiment. In an embodiment, the integrated circuit 910 includes a processor 912. As used herein, the processor 912 may mean any type of circuit such as, but not limited to, a microprocessor, a microcontroller, a graphics processor, a digital signal processor, or another processor. In an embodiment, the processor 912 includes, or is coupled with, a semiconductor package. In one embodiment, the integrated circuit 910 or the processor 912 is part of a semiconductor package that comprises an underfill encapsulant that has been dispensed or collected in accordance with any of the embodiments and their equivalents as set forth in this disclosure. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM). In one embodiment, the on-die memory 916 may be packaged with a suitable packaging process to form a semiconductor package comprising an underfill encapsulant that has been dispensed or collected in accordance with any of the embodiments and their equivalents as set forth in this disclosure.

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also include embedded memory 948 such as the first die in a die stack, according to an embodiment. In one embodiment, the embedded memory 948 part of a semiconductor package that comprises an underfill encapsulant that has been dispensed or collected in accordance with any of the embodiments and their equivalents as set forth in this disclosure.

In an embodiment, the electronic system 900 also includes a display device 950 and an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

At least one of the integrated circuits 910 or 911 can be implemented in a number of different embodiments, including a semiconductor package, an electronic system, a computer system, one or more methods of fabricating an integrated circuit, and one or more methods of fabricating a semiconductor package. In one embodiment, at least one of the integrated circuits is part of a semiconductor package that comprises an underfill encapsulant that has been dispensed or collected in accordance with any of the embodiments and their equivalents as set forth in this disclosure. The elements, materials, geometries, dimensions, and sequence of operations can all be varied to suit particular I/O coupling requirements including array contact count, array contact configuration for a microelectronic die embedded in a processor mounting substrate. A foundation substrate may be included, as represented by the dashed line of FIG. 9. Passive devices may also be included, as is also depicted in FIG. 9.

Reference throughout this specification to “one embodiment,” “an embodiment,” “another embodiment” and their variations means that a particular feature, structure, configuration, or characteristic described in connection with the embodiment is included in at least one embodiment. Thus, the appearances of the phrase “for one embodiment,” “In an embodiment,” “for another embodiment,” “in one embodiment,” “in an embodiment,” “in another embodiment,” or their variations in various places throughout this specification are not necessarily referring to the same embodiment. Furthermore, the particular features, structures, configurations, or characteristics may be combined in any suitable manner in one or more embodiments.

The terms “over,” “to,” “between,” “onto,” and “on” as used in the foregoing specification refer to a relative position of one layer with respect to other layers. One layer “over” or “on” another layer or bonded “to” or in “contact” with another layer may be directly in contact with the other layer or may have one or more intervening layers. One layer “between” layers may be directly in contact with the layers or may have one or more intervening layers.

The description provided above in connection with one or more embodiments as described herein that is included as part of a process of forming semiconductor packages may also be used for other types of IC packages and mixed logic-memory package stacks. In addition, the processing sequences may be compatible with both wafer level packages (WLP), and integration with surface mount substrates such as LGA, QFN, and ceramic substrates.

In the foregoing specification, abstract, and/or figures, numerous specific details are set forth, such as specific materials and processing operations, in order to provide a thorough understanding of embodiments described herein. It will, however, be evident that any of the embodiments described herein may be practiced without these specific details. In other instances, well-known features, such as the integrated circuitry of semiconductive dies, are not described in detail in order to not unnecessarily obscure embodiments described herein. Furthermore, it is to be understood that the various embodiments shown in the Figures and described in connection with the Figures are illustrative representations and are not necessarily drawn to scale. Thus, various modifications and/or changes may be made without departing form the broader spirit and scope of the embodiments described in connection with the foregoing specification, abstract, and/or Figures. As used herein, the phrases “A or B”, “A and/or B”, “one or more of A and B”, and “at least one of A or B” means (A), (B), or (A and B).

Examples of the embodiments described herein are set forth below. It is to be appreciated that the examples are illustrative examples not exhaustive examples.

Example embodiment 1: A needle dispenser comprises a reservoir and a needle coupled to the reservoir. A tip of the needle is comprised of a first material and a body of the needle that comprises a second material is coupled to the tip of the needle. The first and second materials differ from each other. The needle comprises a plurality of channels extending along a length of the needle.

Example embodiment 2: The needle dispenser of example embodiment 1, wherein the first material is more compliant than the second material.

Example embodiment 3: The needle dispenser of any one of example embodiments 1-2, wherein the first material comprises a rubber, a compliant polymer, or a combination thereof.

Example embodiment 4: The needle dispenser of any one of example embodiments 1-3, wherein a core of the needle comprises a hydrophilic material.

Example embodiment 5: The needle dispenser of any one of example embodiments 1-4, further comprising: a plurality of openings through sidewall surfaces of the needle, wherein the plurality of openings expose portions of the core.

Example embodiment 6: The needle dispenser of any one of example embodiments 1-5, wherein an outer surface of the needle comprises a hydrophobic material.

Example embodiment 7: The needle dispenser of any one of example embodiments 1-6, wherein a center line of the body of the needle is parallel to a center line of the body of the reservoir.

Example embodiment 8: The needle dispenser of any one of example embodiments 1-7, wherein a center line of the tip of the needle intersects the center of line of the body of the needle.

Example embodiment 9: The needle dispenser of any one of example embodiments 1-7, wherein a center of line of the tip of the needle is parallel to the center line of the body of the needle.

Example embodiment 10: The needle dispenser of any one of example embodiments 1-9, wherein the tip of the needle is tapered or flared.

Example embodiment 11: A semiconductor package comprises: a substrate; a device positioned on the substrate; one or more interconnects coupling the device to the substrate; and an underfill encapsulant encapsulating the one or more interconnects. The underfill encapsulant has a plurality of sides that extend outward from under the device. A side of the plurality of sides has a concave profile.

Example embodiment 12: The semiconductor package of example embodiment 11, wherein a distance between an edge of the device and an adjacent edge of the side of the underfill encapsulant that has the concave profile ranges from 0.125 millimeters (mm) to 0.5 mm.

Example embodiment 13: The semiconductor package of any one of example embodiments 11-12, wherein the underfill encapsulant comprises a void therein.

Example embodiment 14: The semiconductor package of any one of example embodiments 11-13, wherein a second side of the underfill encapsulant has a sloped profile.

Example embodiment 15: A method comprises dispensing, using a needle dispenser, an underfill encapsulant under a device coupled to a substrate using one or more interconnects. The needle dispenser comprises a reservoir and a needle coupled to the reservoir. A tip of the needle comprises a first material. A body of the needle that is coupled to the tip of the needle comprises a second material that differs from the first material. The needle comprises a plurality of channels extending along the needle.

Example embodiment 16: The method of example embodiment 15, further comprising contacting the tip of the needle with a surface of the substrate during the dispensing of the underfill encapsulant.

Example embodiment 17: The method of any one of example embodiments 15-16, wherein the tip of the needle is under the device and within an outer perimeter of the device during the dispensing.

Example embodiment 18: The method of any one of example embodiments 15-17, wherein the first material is more compliant than the second material.

Example embodiment 19: The method of any one of example embodiments 15-18, wherein an outer perimeter of the dispensed underfill encapsulant is larger than an outer perimeter of the device and wherein at least one sidewall surface defining the outer perimeter of the dispensed underfill encapsulant has a concave profile.

Example embodiment 20: The method of any one of any one of example embodiments 15-19, further comprising: collecting, using the needle dispenser, at least some of the dispensed underfill encapsulant under the device such that a sidewall surface defining at least one part of an outer perimeter of the dispensed underfill encapsulant has a desired profile.

Example embodiment 21: A packaged system comprises: a motherboard; a semiconductor package; one or more interconnects coupling the semiconductor package to the motherboard; and an underfill encapsulant encapsulating the one or more interconnects. The underfill encapsulant has first and second sides that extend outward from under the semiconductor package. The first side has a concave profile.

Example embodiment 22: The packaged system of example embodiment 21, wherein a distance between an edge of a keep-out zone and a corresponding edge of the first device that is parallel to the edge of the keep-out zone is less than or equal to 0.5 millimeters (mm).

Example embodiment 23: The packaged system of any one of example embodiments 21-22, wherein the first side of the plurality of sides has a non-linear shape.

Example embodiment 24: The packaged system of any one of example embodiments 21-23, wherein a second side of the plurality of sides has a sloped profile.

Example embodiment 25: The packaged system of any one of example embodiments 21-24, wherein the second side of the plurality of sides comprises notches.

1. A needle dispenser, comprising:
a reservoir; and
a needle coupled to the reservoir,
wherein a tip of the needle is comprised of a first material,
wherein a body of the needle is coupled to the tip of the needle, the body comprising a second material,
wherein the first and second materials differ from each other, and
wherein the needle comprises a plurality of channels extending along a length of the needle.

2. The needle dispenser of claim 1, wherein the first material is more compliant than the second material.

3. The needle dispenser of claim 2, wherein the first material comprises a rubber, a compliant polymer, or a combination thereof.

4. The needle dispenser of claim 1, wherein a core of the needle comprises a hydrophilic material.

5. The needle dispenser of claim 4, further comprising:
a plurality of openings through sidewall surfaces of the needle, wherein the plurality of openings expose portions of the core.

6. The needle dispenser of claim 1, wherein an outer surface of the needle comprises a hydrophobic material.

7. The needle dispenser of claim 1, wherein a center line of the body of the needle is parallel to a center line of the body of the reservoir.

8. The needle dispenser of claim 7, wherein a center line of the tip of the needle intersects the center of line of the body of the needle.

9. The needle dispenser of claim 7, wherein a center of line of the tip of the needle is parallel to the center line of the body of the needle.

10. The needle dispenser of claim 1, wherein the tip of the needle is tapered or flared.

11. A semiconductor package, comprising:
a substrate;
a device positioned on the substrate;
one or more interconnects coupling the device to the substrate; and
an underfill encapsulant encapsulating the one or more interconnects, the underfill encapsulant having a plurality of sides that extend outward from under the device, wherein a side of the plurality of sides has a concave profile.

12. The semiconductor package of claim 11, wherein a distance between an edge of the device and an adjacent edge of the side of the underfill encapsulant that has the concave profile ranges from 0.125 millimeters (mm) to 0.5 mm.

13. The semiconductor package of claim 11, wherein the underfill encapsulant comprises a void therein.

14. The semiconductor package of claim 11, wherein a second side of the underfill encapsulant has a sloped profile.

15. A method, comprising:
dispensing, using a needle dispenser, an underfill encapsulant under a device coupled to a substrate using one or more interconnects, the needle dispenser comprising:
a reservoir; and
a needle coupled to the reservoir,
wherein a tip of the needle is comprised of a first material,
wherein a body of the needle that is coupled to the tip of the needle comprises a second material that differs from the first material, and
wherein the needle comprises a plurality of channels extending along the needle.

16. The method of claim 15, further comprising contacting the tip of the needle with a surface of the substrate during the dispensing of the underfill encapsulant.

17. The method of claim 16, wherein the tip of the needle is under the device and within an outer perimeter of the device during the dispensing.

18. The method of claim 15, wherein the first material is more compliant than the second material.

19. The method of claim 15, wherein an outer perimeter of the dispensed underfill encapsulant is larger than an outer perimeter of the device and wherein at least one sidewall surface defining the outer perimeter of the dispensed underfill encapsulant has a concave profile.

20. The method of claim 15, further comprising:
collecting, using the needle dispenser, at least some of the dispensed underfill encapsulant under the device such that a sidewall surface defining at least one part of an outer perimeter of the dispensed underfill encapsulant has a desired profile.

21. A packaged system, comprising:
a motherboard;
a semiconductor package;
one or more interconnects coupling the semiconductor package to the motherboard; and
an underfill encapsulant encapsulating the one or more interconnects, the underfill encapsulant having first and second sides that extend outward from under the semiconductor package, wherein the first side has a concave profile.

22. The packaged system of claim 21, wherein a distance between an edge of a keep-out zone and a corresponding edge of the first device that is parallel to the edge of the keep-out zone is less than or equal to 0.5 millimeters (mm).

23. The packaged system of claim 22, wherein the first side of the plurality of sides has a non-linear shape.

24. The packaged system of claim 22, wherein a second side of the plurality of sides has a sloped profile.

25. The packaged system of claim 24, wherein the second side of the plurality of sides comprises notches.
